(19) United States
(12) Patent Application Publication
(10) Pub. No.: US 2006/0054926 A1
(43) Pub. Date: Mar. 16, 2006

(54) High electron mobility transistor piezoelectric structures

(76) Inventor: Hacene Lahreche, Paris (FR)

Correspondence Address: WINSTON & STRAWN LLP, 1700 K STREET, N.W., WASHINGTON, DC, 20006, US

(21) Appl. No.: 11/004,411

(22) Filed: Dec. 3, 2004

(30) Foreign Application Priority Data
Sep. 13, 2004 (FR) 0409674

(51) Int. Cl. H01L 31/0328

(52) U.S. Cl. 257/194

(57) ABSTRACT

Piezoelectric semiconductor structures and methods for fabricating the same are described. In an embodiment, the piezoelectric semiconductor structure includes a support substrate, a channel layer arranged on one side of the support substrate, and a barrier layer formed on the channel layer. The barrier layer is made of alternating binary alloy layers of Type III-Type V semiconductor materials.

### BACKGROUND

1. Field of the Invention

This invention generally relates to manufacturing semiconductor substrates for use in making electronic components. In particular, the invention pertains to a piezoelectric semiconductor structure that includes a support substrate, a channel layer arranged on one side of the support substrate, and a barrier layer formed on the channel layer. The barrier layer comprises alternating binary alloy layers of Type III-Type V semiconductor materials.

2. Background Art

Semiconductor structures based on nitrides (Type III elements) found in the periodic table occupy an increasingly important place in the electronic and optoelectronic fields. These materials can be used to manufacture High Electron Mobility Transistors (HEMTs) which are used in high frequency and high power electronic circuits.

FIG. 1 is an example of an HEMT having a semiconductor structure made of Type III-Type N materials, or nitrides of Type III elements (such as InN, GaN, or AlN). The structure includes a barrier layer 20 made of gallium and aluminum nitride (AlGaN) provided on a channel layer 21 made of gallium nitride (GaN) that is provided on a support 22. The HEMT transistor also comprises a source electrode 23 and a drain electrode 24 on the front face 25 of the barrier layer 20 of AlGaN, and a grid electrode 26 between the source electrode 23 and the drain electrode 24.

Due to the presence of aluminum in the AlGaN barrier layer 20, the prohibited energy band of the barrier layer is wider than that of the channel layer 21 of GaN. Silicon impurities in the AlGaN barrier layer 20 supply electrons to the crystal that tend to accumulate in a region 27 with the lowest potential (i.e., a quantum well), which is located just under the interface 28 between the AlGaN barrier layer 20 and the GaN channel layer 21. A sheet of electrons 27 forms a two-dimensional electron gas (2 DEG). The mobility of electrons in this gas is high since they are physically separated from the silicon atoms residing in the AlGaN barrier layer 20.

The first studies of Type III-Type N semiconductor structures were conducted during the 1970s, but the real advantage of this type of material only became clear after p-type conduction was obtained in a GaN channel layer, followed by marketing of blue diodes by Nichia Chemicals. Devices based on AlGaN/GaN structures with two-dimensional electron gases now have much better characteristics than corresponding products of other materials. Semiconductor structures based on Type III-Type N form a very innovative semiconductor system, and have the following specific features: a prohibited band width varying from 0.8 eV to 6.2 eV, the possibility of making continuous alloys of AlGaN, which enables the production of heterostructures with a large degree of freedom, and a very weak crystalline mesh parameter mismatch between gallium nitride (GaN) and aluminum nitride (AlN). Thus, complex structures can be made without creation of crystalline defects according to the following formula:
Δa/a=(a_{GaN}−a_{AlN})/a_{GaN}=1%;

wherein a_{GaN} is the mesh parameter of GaN, a_{AlN} is the mesh parameter of AlN, and Δa/a is the mesh parameter mismatch (a mesh parameter mismatch less than or equal to 1% is the sign of quasi-pseudomorphic coherent growth). Such a complex structure has excellent electronic properties (good mobility of electrons, high saturation speed, high breakdown field), excellent thermal and chemical stability, good thermal properties (dissipation of heat), and the presence of a strong polarization field to obtain large charge transfers in two-dimensional electron gases.

Therefore, semiconductor structures based on Type III-Type N materials exhibit better performance characteristics than semiconductor structures based on “classical” Type III-Type V materials, particularly with regard to the mobility of charge carriers and the charge density.

Mobility of Charge Carriers

From the point of view of structure fabrication, mobility and the current density per unit surface area of AlGaN/GaN structures are governed by four parameters. The parameters include the defect density in the layers, the surface roughness (RMS) and the chemical roughness at the AlGaN/GaN interface (alloy disorder in the AlGaN barrier layer), the distance from the electron gas to the interface (which can be modulated by inserting a spacer (undoped potential barrier) to limit diffusion of electrons at the interface), and the stress in the HEMT structure (in the AlGaN and GaN layers). The stress influences the piezoelectric field. It is noted that there is also an intense spontaneous polarization field in wurtzite heterostructures that participate in the charge transfer.

Charge Density

Exceptional charge transfers observed in AlGaN/GaN structures (nₛ˜1020−3×10¹³ cm⁻² ) are induced by a particular polarization field: the piezoelectric polarization field. This is also referred to as a piezo-induced High Electron Mobility Transistor (Piezo-HEMT). AlGaN/GaN structures have a Wurtzite-type hexagonal structure. Piezo-electric polarization originates from the non-centro symmetry of this Wurtzite structure.

There are several models that describe the piezo-electric polarization phenomenon. The simplest is the Ambacher et al. model that is briefly summarized below with reference to FIG. 2. Starting from this model, it is possible to determine what material parameters have an influence on the charge density of transistor structures that are based on Type III-Type N based semiconductor materials.

FIG. 2 illustrates a structure having a front face 1 or growth face that is terminated with Ga and Al. This structure includes a support 2, a GaN channel layer 3, and an AlGaN barrier layer 4. The support 2 is a semiconductor or non-semiconductor material. For example, the support 2 may be made of SiC or Si. The GaN channel layer 3 is deposited on the front face 5 of the support 2. This GaN channel layer 3 is relaxed. The AlGaN barrier layer 4 is located on the front face 6 of the GaN channel layer 3. This AlGaN barrier layer 4 is stressed. The AlGaN barrier layer 4 is an AlₓGa₁₋ₓN type alloy where x represents the molar fraction of the AlₓGa₁₋ₓN alloy.

If there is no external electric field, the total polarization field P of an AlₓGa₁₋ₓ, N/GaN structure along an axis [0001] is equal to the sum of a spontaneous polarization field P_{SP} and a piezoelectric polarization field P_{PE} induced by stress in the AlₓGal₁₋ₓN barrier layer. The spontaneous polarization field P_{SP}(X) in the AlₓGa₁₋ₓN barrier layer is expressed as a function of spontaneous polarization constants of allium nitride (GaN) and aluminum nitride (AlN). Assuming a linear variation:
P_{SP}(x)=−0.52x−0.029 C/m² (1)

where x represents the molar fraction of the AlₓGa₁₋ₓN alloy.

The sign of the spontaneous polarization field P_{SP} will depend on the polarity of the crystal. In the classical case of a substrate 1 for which the growth face is terminated by a gallium layer (such as aluminum or indium), the spontaneous polarization field P_{SP} is negative, in other words is opposite the growth axis [0001]. Therefore, the spontaneous polarization field P_{SP} points from the growth face 1 towards the support 2.

The piezoelectric polarization field P_{PE}(X) in the AlₓGa₁₋ₓN barrier layer is expressed as a function of piezoelectric constants e₃₃(x) and e₃₁(x) of the alloy AlₓGa₁₋ₓN calculated from the piezoelectric constants of GaN and AlN:
P_{PE}(x)=e₃₃(x)εₓₓ+e₃₁(x)(εₓₓ+ε_{yy}) (2)

wherein x represents the molar fraction of the alloy AlₓGa₁₋ₓN, e₃₃(x) and e₁₃(x) are the piezo-electric constants of the AlₓGa₁₋ₓN alloy, and εₓₓ, ε_{yy} and ε_{zz}, represent deformations of the length, width and height of the AlₓGa₁₋ₓN alloy.

If the deformations εᵢⱼ are developed in equation (2) as a function of the elastic constants Cij(x) of the AlₓGa₁₋ₓN alloy and the mesh parameters of the GaN channel layer and the AlₓGa₁₋ₓN barrier layer, then the result is:

$${P}_{PE} ( x ) = 2 \frac{a ( x ) - {a}_{0}}{{a}_{0}} ( {e}_{31} ( x ) - {e}_{33} ( x ) \frac{{C}_{13} ( x )}{{C}_{33} ( x )} ) \qquad ( 3 )$$

where in a₀ represents the mesh parameter of GaN, a(x) represents the mesh parameter of the AlₓGa₁₋ₓN alloy, and C₁₃(x) and C₃₃(x) represent the elastic constants of the AlₓGa₁₋ₓN alloy.

The elastic constants C₁₃(x) and C₃₃(X) of the AlₓGa₁₋ₓN alloy are calculated starting from elastic constants C₁₃ and C₃₃ of GaN and AlN assuming a linear variation as a function of x. The values of the elastic constants C₁₃ and C₃₃ of GaN and AlN commonly used in the literature are as given by Wright et al. These values agree well with experimental data. In equation (3), the quantity “e₃₁(x)−e₃₃(X)×(C₁₃(X)/C₃₃(X))” is negative for the entire composition range. Consequently, the piezoelectric polarization P_{PE}(X) will be negative for the barrier layer of AlₓGa₁₋ₓN stressed in tension.

The polarization discontinuity at the AlₓGa₁₋ₓN/GaN interface 6 between the barrier layer of AlₓGa₁₋ₓN and the channel layer of GaN generates a positive charge distribution at the AlₓGa₁₋ₓN/GaN interface 6, for which the density is written as follows:
σ=P(AlGaN)−P(GaN)
σ=P_{SP}(AlGaN−P_{PE}(AlGaN)−P_{SP}(GaN) (4)

Equations (1), (3) and (4) are used to calculate the charge density σ/e (where e=1.6×10¹⁹ C) for stressed structures.

If the aluminum content in the AlₓGa₁₋ₓN barrier layer is between 5% and 30%, then the charge density induced by the polarization is between 2×10¹² cm⁻² and 2×10¹³ cm⁻². In order to compensate for this high positive charge, a two-dimensional electron gas will be formed at the AlₓGa₁₋ₓN/GaN interface 6. Therefore, there is an additional contribution to that induced by the band structure.

The simple model by Ambacher et al described above demonstrates dependence between the charge density induced by polarization and the concentration of aluminum in the AlₓGa₁₋ₓN barrier layer. Thus, the charge carrier mobility and charge density properties of transistor structures obtained starting from a Type III-Type N-based semiconductor material depend on parameters such as the chemical roughness at the AlGaN/GaN interface and the aluminum concentration in the AlGaN barrier. These parameters are related to methods of producing the semiconductor structure based on Type III-Type N, and generate problems with the reliability of transistor structures made on the semiconductor material.

Prior art electronic circuits based on Gallium nitride (GaN) used in high frequency and high power applications suffer from reliability problems. One reason for such problems is that non-homogenous electronic density distributions exist in these structures that originate from alloy disorders at the atomic and micrometric scale. Therefore, a need exists for improving the reliability of transistor structures based Type III-Type N semiconductor materials, particularly by improving methods of producing the semiconductor structures utilizing Type III-Type N materials.

### SUMMARY OF THE INVENTION

Presented are piezoelectric semiconductor structures and methods for fabricating the same that overcome the problems of the prior art discussed above. In an embodiment, the piezoelectric semiconductor structure includes a support substrate, a channel layer arranged on one side of the support substrate, and a barrier layer formed on the channel layer. The barrier layer is made of alternating binary alloy layers of Type III-Type V semiconductor materials.

In a beneficial implementation, the semiconductor structure includes a barrier layer that is perfectly ordered along a crystalline axis. Advantageously, each binary alloy layer of the barrier layer comprises a number of atomic monolayers. The number of atomic monolayers may be between at least about 1 and about 40. In addition, the number of atomic monolayers in at least some of, or all of, the alternating barrier alloy layers may be different. Further, the number of atomic monolayers in at least some of the alternating barrier alloy layers may increase or decrease with distance from the support substrate. In an advantageous embodiment, the barrier layer is between about 2 nm and about 500 nm thick. Advantageously, the barrier layer may be a ternary pseudo-alloy comprising at least one of AlGaN, InGaN, AlBN, InBN, or InAlN, and the binary alloy layers forming the barrier layer may be made of at least one of AlN, GaN, BN, or InN.

In another advantageous embodiment, the channel layer is made of at least one of AlN, GaN, BN or InN. The channel layer may be a ternary pseudo-alloy made of at least one of AlGaN, InGaN, AlBN, InBN, or InAlN, and the ternary pseudo-alloy may include alternating layers of binary alloys chosen from among AlN, GaN, BN, or InN. In addition, the support may be made of at least one of silicon, SiC, AlN, sapphire or GaN.

In a beneficial implementation, a buffer layer is provided between the support substrate and the channel layer. The buffer layer may be made of at least one of AlGaN or GaN, and the buffer layer may be made of alternating binary alloy layers of AlN and GaN.

The buffer layer may also include alternating binary alloy layers that each include a number of atomic monolayers. In an embodiment, the number of atomic monolayers is between at least about 1 and about 40. In addition, the number of atomic monolayers in at least some, or all, of the alternating barrier alloy layers is different. In beneficial embodiments, the number of atomic monolayers in at least some of the alternating barrier alloy layers increases or decreases with distance from the support substrate.

Another aspect according to the invention concerns a method for fabricating a piezoelectric semiconductor structure. The method includes providing a support and channel layer, and providing a barrier layer on the channel layer by alternately depositing at least one atomic monolayer of a first binary alloy and at least one atomic monolayer of a second binary alloy until a predetermined barrier layer thickness is obtained.

In a beneficial embodiment according to this aspect of the invention, the barrier layer is perfectly ordered along a crystalline axis. In addition, the atomic monolayers of the first and second binary alloys are deposited over the entire surface of the channel layer.

In an implementation, the first and second binary alloys of the barrier layer are chosen from among AlN, InN, GaN, or BN. In an advantageous embodiment, an AlGaN barrier layer is fabricated by alternately depositing at least one atomic monolayer of GaN and at least one atomic monolayer of AlN until the AlGaN barrier layer reaches a predetermined thickness. In addition, the channel layer is grown over the entire surface of the support, and may be made of at least one of AlN, or GaN, or BN or InN or InGaN. Further, the support layer may be made of at least one of silicon, or SiC, or AlN, or sapphire, or GaN.

Another beneficial embodiment according to the invention includes depositing a buffer layer of at least one of GaN or AlGaN. In an advantageous implementation, the buffer layer is provided on the support before providing the channel layer on the buffer layer, the buffer layer being provided by alternately depositing at least one atomic monolayer of a first binary alloy and at least one atomic monolayer of a second binary alloy until a predetermined buffer layer thickness is obtained. Advantageously, the first binary alloy of the buffer layer is GaN and the second binary alloy of the buffer layer is AlN.

### BRIEF DESCRIPTION OF THE FIGURES

Other aspects, purposes and advantages of the invention will become clear after reading the following detailed description with reference to the attached drawings, in which:

FIG. 1 is a simplified cross-sectional view of a conventional semiconductor structure based on a nitride of a Type III element on which an HEMT type transistor was made;

FIG. 2 is a simplified cross-sectional view of a conventional semiconductor structure based on a nitride of a Type III element;

FIG. 3 is a simplified sectional view of an interface between a binary material and a ternary material;

FIG. 4 is a simplified sectional view of a ternary material;

FIG. 5a is a simplified sectional view of a ternary material illustrating the alloy order in the [001] symmetric planes;

FIG. 5b is a simplified sectional view of a ternary material illustrating the alloy order in the [1-101] asymmetric planes;

FIG. 6a is a simplified sectional view of binary and ternary material layers in the case of a standard ternary material;

FIG. 6b is a simplified sectional view of binary and ternary material layers in the case of an ideal ternary material;

FIG. 6c is a simplified sectional view of binary and ternary materials obtained according to an embodiment of the invention;

FIG. 7a shows a simplified sectional view of a first semiconductor structure according to the invention;

FIG. 7b shows a simplified sectional view of a second semiconductor structure according to the invention;

FIG. 7c shows a simplified sectional view of a third semiconductor structure according to the invention;

FIG. 7d shows a simplified sectional view of a fourth semiconductor structure according to the invention;

FIG. 8 is a simplified sectional view of a ternary material obtained by the method according to the invention, at the atomic level.

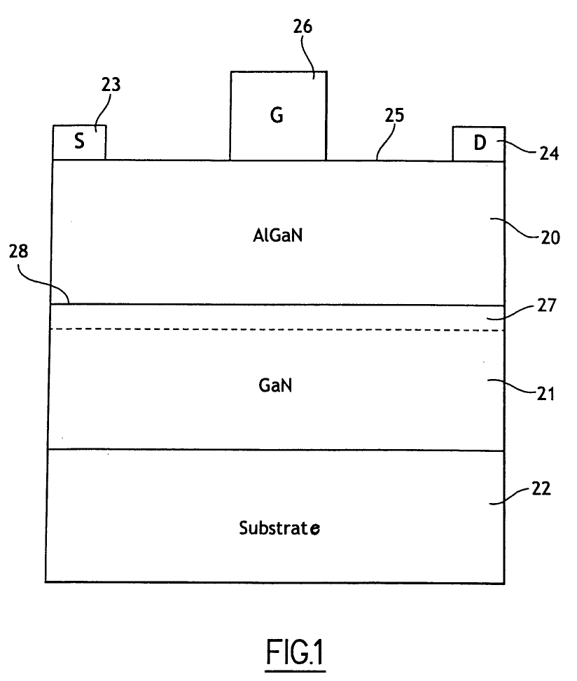

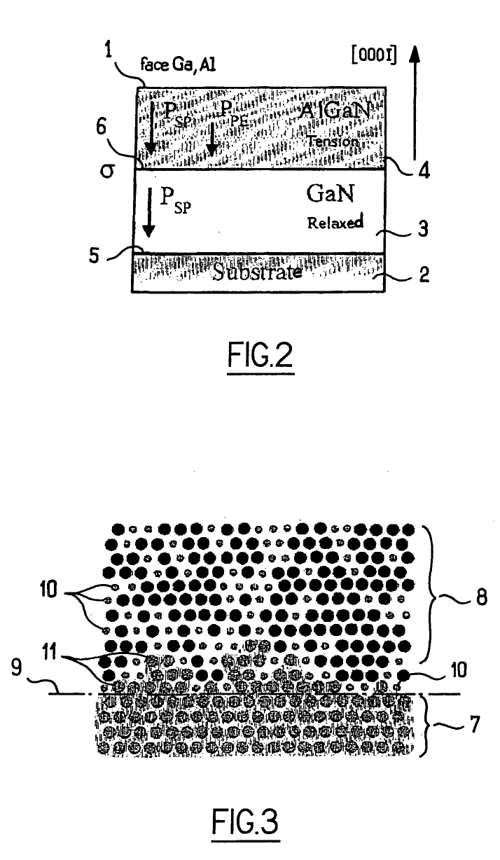

### DETAILED DESCRIPTION OF THE PREFERRED EMBODIMENTS

The present invention provides methods for manufacturing semiconductor structures based on nitrides of Type III elements (Al, Ga, In)/N perfectly ordered along a preferred crystalline axis. To obtain this result, the ternary alloy barrier layer is replaced by a barrier layer that includes alternating binary alloy barrier layers. The lack of fluctuation in the composition of these structures improves electron transport properties and makes the distribution more uniform.

The invention relates to a semiconductor structure or substrate based on elements in columns III and V in the periodic table for use, for example, to fabricate HEMT type transistor structures. Such semiconductor structures include a support, a channel layer on the support and a barrier layer on the channel layer, wherein the barrier layer is composed of alternating binary semiconductor alloy layers.

A semiconductor structure that includes a barrier layer composed of alternating binary alloy layers has the following advantages. It has zero alloy disorder at the atomic level, zero alloy non-homogeneities at the nanometric level and at the microscopic level, a perfect alloy order according to a privileged crystalline axis, a maximum piezoelectric field along a preferred crystalline axis, an optimum electron piezoelectric injection, a very uniform electronic density per unit surface area, reduced electronic diffusion at interfaces and in the barrier layer due to the zero alloy disorder, and improved structure reliability due to the absence of any alloy non-homogeneities.

It should be understood that when a layer A is mentioned as being “on” a layer B, it may be directly on layer B, or it may be located above layer B and separated from layer B by one or several intermediate layers. It should also be understood that when a layer A is said to be “on” a layer B, it may cover the entire surface or just a portion of layer B.

In several beneficial, non-limitative aspects, the semiconductor structure includes one more of the following features. Each binary alloy layer is composed of atomic monolayers, and the number of atomic monolayers in each binary alloy layer forming the barrier layer may be between about 1 and about 40, and preferably between about 1 and about 20, and more preferably between about 2 and about 10. The number of atomic monolayers in each binary alloy layer that forms the barrier layer may vary between a first value on a back face of the barrier layer and a second value on a front face of the barrier layer, wherein the back face is closer to the support than the front face. The first and second values are between about 1 and about 40, preferably between about 1 and about 20, and more preferably between about 2 and about 10. The thickness of the barrier layer may be between about 2 nm and about 500 nm.

The semiconductor structure may also include a buffer layer between the support and the channel layer, and the buffer layer is a material chosen from among AlGaN and GaN. In a preferred embodiment, the buffer layer is a ternary pseudo-alloy of AlGaN, the pseudo alloy being composed of alternating binary alloy layers of AlN and GaN. The barrier layer may also be a ternary pseudo-alloy of AlGaN, or InGaN, or AlBN, or InBN, or InAlN. The binary alloy layers that form the barrier layer may be made from materials chosen from among AlN, GaN, BN, and InN. In a preferred embodiment, the channel layer is made of a material chosen from among AlN, GaN, BN, and InN. Moreover, the channel layer is a ternary pseudo-alloy of AlGaN, or InGaN, or AlBN, or InBN, or InAl.

The ternary pseudo alloy is preferably made of alternating layers of binary alloys chosen from among AlN, GaN, BN, or InN. Further, the support is preferably made of a material chosen from among silicon, SiC, AlN, sapphire and GaN. The thickness of each layer of binary alloy of the buffer layer can vary between a first value on a back face of the buffer layer and a second value on a front face of the buffer layer, wherein the back face is closer to the support than the front face.

The invention also relates to a method for fabricating a semiconductor substrate that includes a support, a channel layer on the support and a barrier layer on the channel layer. The barrier layer is composed of alternating layers of binary alloys. The technique includes growing he channel layer on the support, creating the barrier layer by depositing at least one atomic monolayer of a first binary alloy, depositing at least one atomic monolayer of a second binary alloy, and repeating these steps until a required thickness is obtained for the barrier layer.

Preferred but non-limiting aspects of the method according to the invention include that the channel layer is grown over the entire surface of the support, and atomic monolayers of the first and second binary alloys are deposited over the entire surface of the channel layer. The method may also include depositing a buffer layer of GaN or AlGaN. A buffer layer of AlGaN may also be created, and its formation may include depositing at least one first binary alloy atomic monolayer of GaN, depositing at least one second binary alloy atomic monolayer of AlN, and repeating these steps, if necessary, until a required thickness is obtained for the buffer layer.

The method may include fabricating the channel layer of AlN, or GaN, or BN or InN or InGaN on a support of silicon, or SiC, or AlN, or sapphire, or GaN. The technique may also include fabricating the barrier layer of AlGaN or InGaN, or AlBN, or InBN, or InAlN by depositing atomic monolayers of the first binary alloy and the second binary alloy, the first and second binary alloys being chosen from among AlN, InN, GaN, BN. In a preferred embodiment, the AlGaN barrier layer is fabricated by depositing at least one atomic monolayer of the first binary alloy of GaN, depositing at least one atomic monolayer of the second binary alloy of AlN, and repeating these depositing steps if necessary, until the required thickness is obtained for the AlGaN barrier layer.

One purpose of the present invention is to provide a method capable of producing a semiconductor structure based on an improved Type III-Type N material. In other words, the material provides for improved transistor structure properties in terms of mobility of carriers, charge density and reliability of the final structure. The applicants studied the material parameters that limit the mobility, charge density and structure reliability properties, and these material parameters include the roughness value at interfaces, alloy fluctuations and alloy order.

Type 1 Non-Homogeneities: Roughness at Interfaces

The roughness observed at interfaces may be physical or chemical. The mobility of electrons in the GaN channel layer of a semiconductor structure based on Type III-Type N materials is particularly sensitive to chemical roughness. The chemical roughness depends on the composition of the structure, and occurs as soon as a ternary material (for example AlGaN, InGaN, InAlN, AlBN, GaBN) is introduced into the structure.

FIG. 3 shows an interface 9 between a GaN channel layer 7 and an Al_{0.3}Ga_{0.7}N barrier layer 8. The GaN channel layer 7 is located below the interface 9, and the Al_{0.3}Ga_{0.7}N barrier layer 8 is located above the interface 9. As shown, some atoms 11 of the GaN channel layer 7 are above the interface 9. Therefore, a roughness phenomenon occurs at the Al_{0.3}Ga_{0.7}N/GaN interface 9.

Type 2 Non-Homogeneities: Alloy Fluctuations

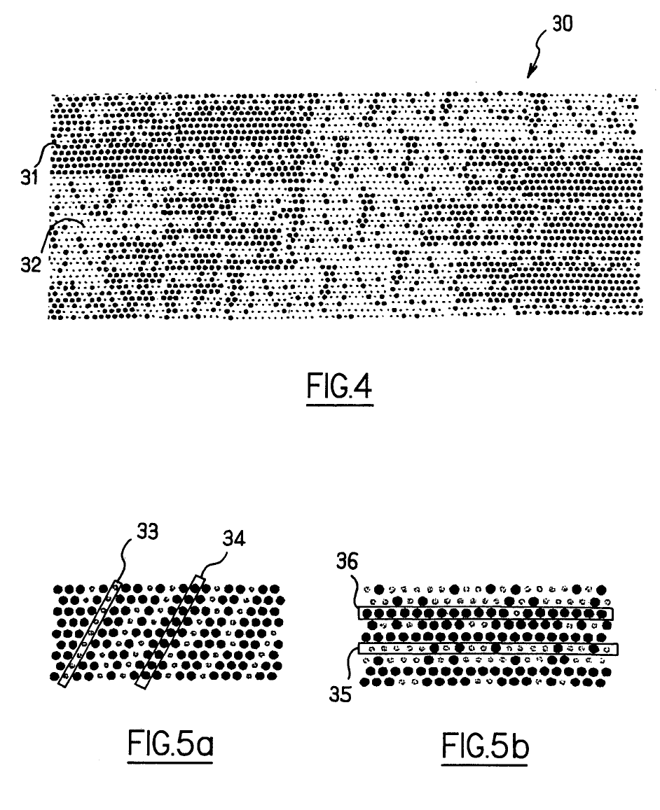

FIG. 4 shows a non-homogenous distribution in a barrier layer 30 made of AlGaN, of a Type III-Type N based semiconductor material. “gallium rich” areas 31 and “aluminum rich” areas 32 are frequently created due to the surface diffusion rates of gallium and aluminum precursors during fabrication of the semiconductor structure, because aggregates form and develop. This type of defect is know as an alloy fluctuation.

Alloy fluctuations reduce the mobility of electrons and play an important role in the reliability of transistors made from Type III-Type N semiconductor materials. In particular, these alloy fluctuations degrade the piezoelectric electron injection so that it becomes non-homogenous, which results in a non-homogenous charge density in the channel of the transistors produced. Alloy fluctuations are a main source of failure of power transistors, since the current density in such transistors is not homogenous.

Type 3 Non-Homogeneities: The Alloy Order

The alloy order is a defect similar to that of an alloy fluctuation, but it is at the atomic level. The alloy order is due to growth parameters and is the result of a partially ordered distribution of the constituent atomic elements of a ternary material. For example, in the case of an AlGaN barrier layer, “aluminum rich” atomic planes can be observed alternating with “aluminum depleted” atomic planes. The average composition of the alloy corresponds to the target, with ordered fluctuations at the atomic level.

The alloy order may appear in several crystalline directions. This alloy order may be induced by growth parameters and stress. In all cases, it is a “spontaneous” order that is not deliberately introduced into the semiconductor structure. Consequently, it is uncontrolled and non-homogenous.

FIG. 5a shows the alloy order in the [1-101] asymmetric planes of an AlGaN barrier layer, which means in planes perpendicular to the [0001] growth axis. “aluminum rich” atomic planes 33 and “aluminum depleted” atomic planes 34 are shown. The alloy order is formed in the [1-101] asymmetric planes when epitaxy production systems are used in which the supports are placed on a rotating plate. This result occurs because aluminum and gallium have a faster depletion rate in the gas or molecular mix used in the method for manufacturing the semiconductor structure (uncontrolled parasite reactions of precursors). Thus, the support will be exposed alternately to an “aluminum rich” gas or molecular mix, then to an “aluminum depleted” gas or molecular mix.

FIG. 5b shows the alloy order in the [001] symmetric planes of an AlGaN barrier layer. “Aluminum rich” atomic planes 35 and “aluminum depleted” atomic planes 36 are shown. The alloy order in the [001] symmetry planes is due to non-homogenous stress distributions and differences in the stability of the crystalline surfaces.

Effects of Type 1, 2 and 3 Non-Homogeneities

The three defect types explained above (roughness at interfaces, alloy fluctuations, and alloy order) occur when conventional methods are used to fabricate the semiconductor structure, and they generate reliability problems for transistors made on the semiconductor structure. As already demonstrated using the Ambacher et al. model, the charge density induced by polarization depends on the aluminum concentration in the AlGaN barrier layer. A local variation ±0.2% of the aluminum content can make the electronic density fluctuate by 2×10¹² cm⁻² or more.

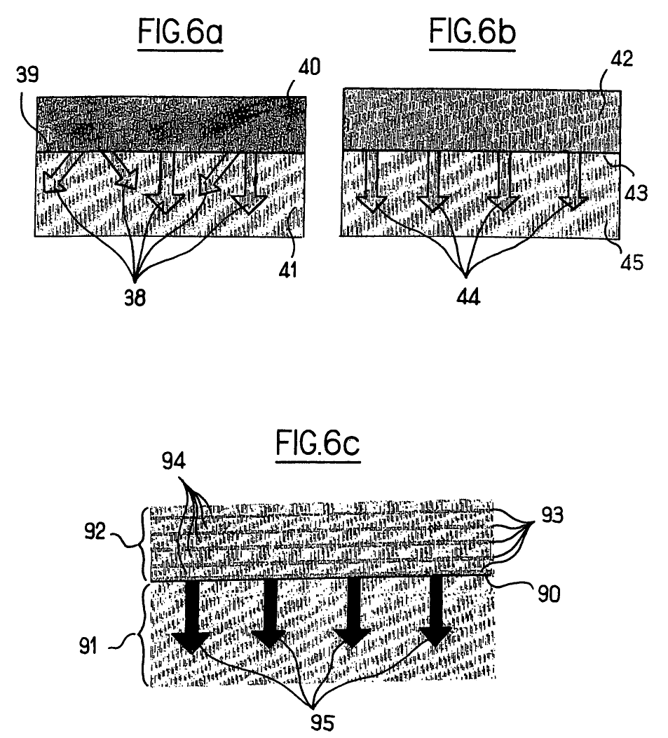

FIG. 6a illustrates use of a standard AlGaN barrier layer 40, wherein the direction and intensity of the piezoelectric field 38 at the interface 39 between the barrier layer 40 and the channel layer 41 locally depends on the distribution of Ga and Al atoms in the barrier layer 40. The direction and intensity of the piezoelectric field will induce fluctuations in the electronic density at this interface 39. Similarly, the power output of a transistor made on the semiconductor structure that includes the standard AlGaN barrier layer will be non-homogenously distributed.

FIG. 6b illustrates the average value of the piezoelectric field 44 for an ideal barrier layer 42. The average value for such an ideal barrier layer is equal to the local value of the field at any point on the interface 43 between the barrier layer 42 and the channel layer 45. Therefore, the electronic density is homogenous at the interface 43.

It is thus important to have a semiconductor structure with a correctly ordered barrier layer in order to eliminate the three types of non-homogeneities mentioned above, and thus to obtain better transistor structure properties. In order to obtain a semiconductor structure with a correctly ordered barrier layer, the applicants replaced the conventional barrier layer made of a ternary alloy (with Type III-Type N-based semiconductor materials) with a barrier layer made of a ternary pseudo-alloy. For the purposes of this disclosure, a ternary “pseudo-alloy” is an alloy composed of alternating atomic monolayers of binary alloys.

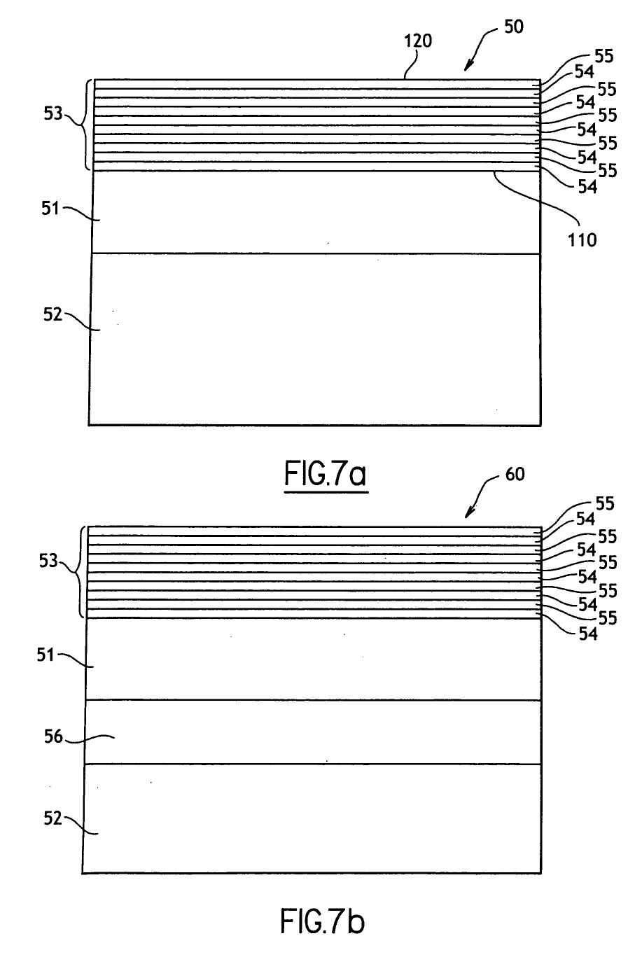

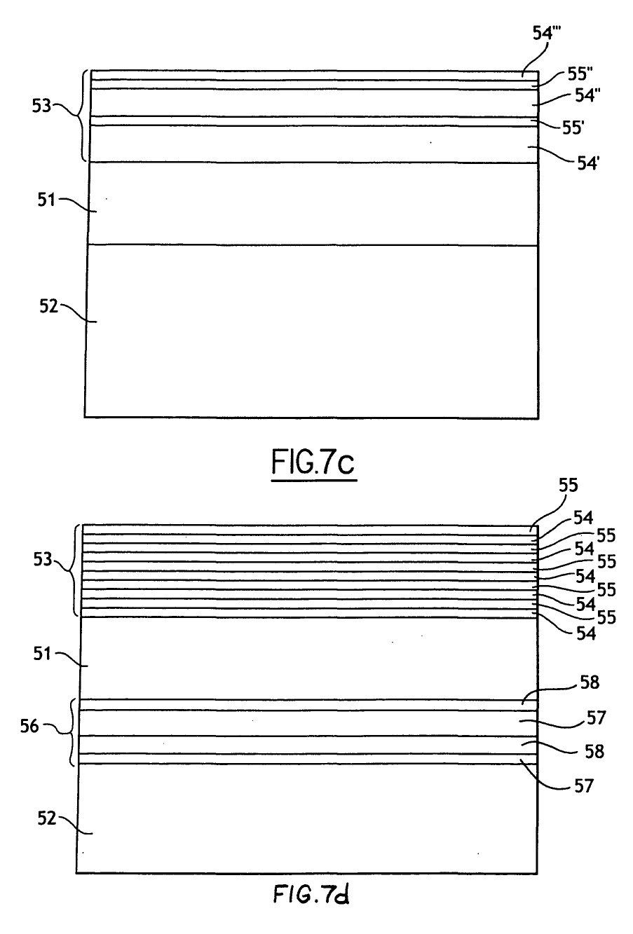

FIG. 7a illustrates a semiconductor structure 50 according to a first embodiment of the invention. This semiconductor structure 50 comprises a channel layer 51 on a support 52, and a barrier layer 53 made of a ternary pseudo-alloy on the channel layer 51.

The support 52 is made of SiC. However, the support could be made of other materials such as Silicon, AlN, sapphire or GaN. The channel layer 51 is a binary alloy of GaN. However, another material could have been chosen for the channel layer 51, such as AlN, BN (boron nitride) or InN (indium nitride). The channel layer 51 is deposited on the support by a method known to those skilled in the art such as Molecular Beam Epitaxy (MBE) or Metal-Organic Chemical Vapor Deposition (MOVD) method.

The barrier layer 53 is a ternary pseudo-alloy of AlGaN. The barrier layer 53 comprises binary alloy layers of GaN 54 and binary alloy layers of AlN 55. The GaN and AlN layers are supplied in an alternating fashion. Each binary alloy layer made of GaN 54 (or AlN 55) is composed of one or several atomic monolayers of GaN (or AlN). The number of atomic monolayers (denoted n_{GaN}) per GaN layer 54 can vary between about 1 and about 40, and preferably between about 1 and about 20, and more preferably between about 2 and about 10. Similarly, the number of atomic monolayers (denoted n_{AlN}) per layer of AlN 55 can vary between about 1 and about 40, and preferably between about 1 and about 20, and more preferably between about 2 and about 10.

A production method known to those skilled in the art such as liquid phase epitaxy, or vapor phase epitaxy, or molecular beam epitaxy is used to grow the barrier layer 53 on the channel layer of GaN. The barrier layer 53 is created by initially depositing a GaN layer 54 in which the number of atomic monolayers n_{GaN} is between about 1 and about 40, preferably between about 1 and about 20 and more preferably between about 2 and about 10. The next step is to deposit an AlN layer in which the number of atomic monolayers n_{AlN} is between about 1 and about 40, preferably between about 1 and about 20, and more preferably between about 2 and about 10. The next step is to deposit alternating layers of GaN and AlN until a predetermined thickness of the barrier layer 53 is obtained, varying between about 2 and about 500 nm. In the embodiment shown in FIG. 7a, the numbers of atomic monolayers n_{GaN} and n_{AlN} are equal. However, the numbers of atomic monolayers n_{GaN} and n_{AlN} could be different.

Since the barrier layer 53 is composed of alternating layers of GaN and AlN, the gas or molecular precursors of Gallium and of Aluminum (or Gallium and Aluminum) are not mixed during the production method and there is no mix depletion phenomenon.

Thus, alloy fluctuations are impossible both at the nanometric and micrometric scales (type 1 non-homogeneities), and at the atomic scale (type 2 and 3 non-homogeneities).

Therefore the structure of the barrier layer 53 is perfectly ordered along the [0001] growth axis. As illustrated in FIG. 6c, this has the effect of eliminating all chemical roughness and consequently limiting the diffusion of electrons at the interface 90 between the channel layer 91 and the barrier layer 92 (this barrier layer being composed of alternating AlN layers 93 and GaN layers 94). In addition, the distribution of the piezoelectric field for which the average value is equal to the local value of the piezoelectric field 95 is optimized at all points on the interface 90. Therefore, the injection of electrons by this field is optimized. Moreover, the distribution of electrons injected into the two-dimensional gas (2 DEG) is perfectly homogenous since the induced piezoelectric field is homogenous. Consequently, this structure provides a means of optimizing the mobility and the surface density of electrons located in the two-dimensional gas (2 DEG).

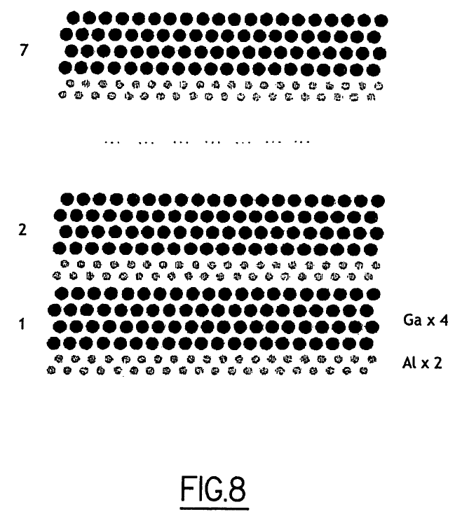

FIG. 8 is an example embodiment of a barrier layer according to this invention. In this example, a 20.5 nm thick barrier layer of AlGaN containing 32.2% of aluminum was replaced by a barrier layer made of a ternary pseudo-alloy:
(AlN n_{AlN}=2/GaN n_{GaN}=4)ₓ₌₇

wherein n_{AlN} is the number of atomic monolayers of AlN, the thickness of an AlN monolayer is e_{AlN}=0.2485 nm, n_{GaN} is the number of atomic monolayers of GaN, the thickness of an GaN monolayer is e_{GaN}=0.2590 nm, and X is the number of periods (AlN n_{AlN}=2/GaN n_{GaN}=4).

In the following formula, Y is the average composition of the barrier layer:
Y=n_{AlN}/(n_{GaN}+n_{AlN})=32.2%,

In the following, E is the equivalent thickness of the barrier layer:
E=X×(n_{AlN}×e_{AlN}+n_{GaN}×e_{GaN})=20.1 nm.

FIG. 7b illustrates a semiconductor structure 60 according to a second embodiment, wherein a buffer layer 56 has been inserted between the channel layer 51 and the support 52. The buffer layer 56 is made of a material chosen from among GaN and AlGaN. This buffer layer facilitates growth of the GaN channel layer, and may be provided by bonding or by depositing the layer in another known manner, such as by epitaxial growth.

FIG. 7c illustrates a semiconductor structure according to a third embodiment. This semiconductor structure includes a support 52, a channel layer 51 and a barrier layer 53. In this embodiment, the barrier layer 53 comprises GaN layers 54′, 54″, 54′″ without the same number of atomic monolayers n_{GaN}. In particular, layers 54′, 54″, 54′″ comprise eight, five and two atomic monolayers of GaN, respectively. These layers alternate with AlN layers 55′ and 55″, the layer 55′ being closest to the support, and the layer 54′″ being furthest from the support. As shown in FIG. 7c, the number of atomic monolayers n_{GaN} per layer of GaN 54′, 54″, 54′″ decreases as the distance from the support 52 increases.

However, it would be possible to have a barrier layer 53 in which the number of atomic monolayers increases with increasing distance from the support 52. Thus, the number of atomic monolayers n_{GaN} per GaN layer can vary along the barrier layer 53. The same is also true regarding the number of monolayers n_{AlN} per AlN layer that vary along the barrier layer 53.

FIG. 7d illustrates a semiconductor structure according to a fourth embodiment. This semiconductor structure includes a support 52, a buffer layer 56, a channel layer 51 and a barrier layer 53. The buffer layer 56 is a ternary pseudo-alloy of AlGaN composed of alternating layers of binary alloy of GaN 57 and binary alloy of AlN 58. The buffer layer 56 has the same characteristics as the ternary pseudo-alloy barrier layer (n_{GaN} and n_{AlN} between about 1 and about 40, preferably between about 1 and about 20, and more preferably between about 2 and about 10 and possibly varying along the buffer layer, etc.). In this embodiment, the buffer layer 56 comprises two GaN layers 57 alternating with two AlN layers 58. Furthermore, the number of atomic monolayers n_{GaN} per GaN layer 57 varies along the buffer layer 56. In particular, the GaN layer 57 closest to the support comprise two atomic monolayers, while the GaN layer furthest from the support comprises four atomic monolayers. Similarly, the number of atomic monolayers n_{AlN} per AlN layer 58 can vary along the buffer layer 56. In this example, the GaN layer 57 closest to the support comprises six atomic monolayers while the AlN layer furthest from the support comprises three atomic monolayers.

Thus, in the embodiment illustrated in FIG. 7d, the numbers of atomic monolayers per layer of GaN and per layer of AlN vary along the buffer layer. In this case, the number of atomic monolayers n_{AlN} vary so as to decrease as the distance from the support increases, and the number of atomic monolayers n_{GaN} varies so that it increases with increasing distance from the support substrate.

The reader should understand that the number of atomic monolayers n_{AlN} and n_{GaN} may be fixed along the buffer layer as was the case for the barrier layer illustrated in FIG. 7a. Further, the buffer layer may be provided by using a known production method such as by epitaxial growth (utilizing, for example, molecular beam epitaxy, liquid phase epitaxy, or vapor phase epitaxy).

In summary, the barrier layer 53 made of an AlGaN ternary pseudo alloy may be denoted as: (AlNn_{alN}/GaNn_{GaN})x, wherein n_{AlN} is a number of atomic monolayers of an AlN layer, where 1≦n_{AlN}≦40, preferably 1≦n_{AlN} 20, or preferably 2≦n_{AlN}≦10. The value of n_{AlN} can vary along the barrier layer. In addition, n_{GaN} is a number of atomic monolayers of a GaN layer where 1≦n_{GaN}≦40, preferably 1≦n_{GaN}≦20, or preferably 2≦n_{GaN}≦10, and where n_{GaN} can vary along the barrier layer. Lastly, X is the number of layers of GaN and AlN.

In the above description, the barrier layer was a pseudo-alloy of AlGaN. It would also have been possible to have chosen to make a barrier layer from a ternary pseudo-alloy composed of AlInN (aluminum and indium nitride), or AlBN (aluminum and boron nitride), InGaN (gallium and indium nitride), BGaN (gallium and boron nitride) or InBN (boron and indium nitride). In this case, the binary alloys forming the ternary pseudo-alloy would have been chosen from among AlN, GaN, BN and InN.

Also in the above description, the described channel layer is a binary alloy of GaN. However, a channel layer composed of a ternary pseudo-alloy of AlGaN, InGaN, AlBN, INBN or InAlN could have been chosen. In this case, the channel layer would have been created using a method identical to that described for creation of the barrier layer, and the binary alloys forming the ternary pseudo-alloy would have been chosen from among AlN, GaN, Bn and InN.

Although some example embodiments of the invention were described in detail above, those skilled in the art will easily understand that many modifications could be made without physically going outside the scope of the disclosure and the advantages described herein. For example, in other embodiments, the nitride element could be replaced by any other element in column V (P, As, etc.) of the periodic table of elements. Consequently, all modifications of this type will be included in the scope of this invention as defined in the attached claims.

What is claimed is:

1. A piezoelectric semiconductor structure, comprising:
a support substrate;
a channel layer arranged on one side of the support substrate; and
a barrier layer formed on the channel layer, wherein the barrier layer comprises alternating binary alloy layers of Type III-Type V semiconductor materials.

2. The semiconductor structure of claim 1, wherein the barrier layer is perfectly ordered along a crystalline axis.

3. The semiconductor structure of claim 1, wherein each binary alloy layer of the barrier layer comprises a number of atomic monolayers.

4. The semiconductor structure of claim 3, wherein the number of atomic monolayers is between at least about 1 and about 40.

5. The semiconductor structure of claim 3, wherein the number of atomic monolayers in at least some of the alternating barrier alloy layers is different.

6. The semiconductor structure of claim 3, wherein the number of atomic monolayers in all of the alternating barrier alloy layers is different.

7. The semiconductor structure of claim 3, wherein the number of atomic monolayers in at least some of the alternating barrier alloy layers increases with distance from the support substrate.

8. The semiconductor structure of claim 3, wherein the number of atomic monolayers in at least some of the alternating barrier alloy layers decreases with distance from the support substrate.

9. The semiconductor structure of claim 1, wherein the barrier layer is between about 2 nm and about 500 nm thick.

10. The semiconductor structure of claim 1, wherein the barrier layer is a ternary pseudo-alloy comprising at least one of AlGaN, InGaN, AlBN, InBN, or InAlN.

11. The semiconductor structure of claim 1, wherein the binary alloy layers forming the barrier layer are made of at least one of AlN, GaN, BN, or InN.

12. The semiconductor structure of claim 1, wherein the channel layer is made of at least one of AlN, GaN, BN or InN.

13. The semiconductor structure of claim 1, wherein the channel layer is a ternary pseudo-alloy made of at least one of AlGaN, InGaN, AlBN, InBN, or InAlN.

14. The semiconductor structure of claim 13, wherein the ternary pseudo-alloy comprises alternating layers of binary alloys chosen from among AlN, GaN, BN, or InN.

15. The semiconductor structure of claim 1, wherein the support is made of at least one of silicon, SiC, AlN, sapphire or GaN.

16. The semiconductor structure of claim 1, which further comprises a buffer layer between the support substrate and the channel layer.

17. The semiconductor structure of claim 16, wherein the buffer layer is made of at least one of AlGaN or GaN.

18. The semiconductor structure of claim 16, wherein the buffer layer is comprised of alternating binary alloy layers of AlN and GaN.

19. The semiconductor structure of claim 16, wherein the buffer layer is comprised of alternating binary alloy layers that each comprise a number of atomic monolayers.

20. The semiconductor structure of claim 19, wherein the number of atomic monolayers is between at least about 1 and about 40.

21. The semiconductor structure of claim 19, wherein the number of atomic monolayers in at least some of the alternating barrier alloy layers is different.

22. The semiconductor structure of claim 19, wherein the number of atomic monolayers in all of the alternating barrier alloy layers is different.

23. The semiconductor structure of claim 19, wherein the number of atomic monolayers in at least some of the alternating barrier alloy layers increases with distance from the support substrate.

24. The semiconductor structure of claim 19, wherein the number of atomic monolayers in at least some of the alternating barrier alloy layers decreases with distance from the support substrate.

25. A method for fabricating a piezoelectric semiconductor structure, which comprises:
providing a support and channel layer; and
providing a barrier layer on the channel layer by alternately depositing at least one atomic monolayer of a first binary alloy and at least one atomic monolayer of a second binary alloy until a predetermined barrier layer thickness is obtained.

26. The method of claim 25, wherein the barrier layer is perfectly ordered along a crystalline axis.

27. The method of claim 25, wherein atomic monolayers of the first and second binary alloys are deposited over the entire surface of the channel layer.

28. The method of claim 25, wherein the first and second binary alloys of the barrier layer are chosen from among AlN, InN, GaN, or BN.

29. The method of claim 25, wherein an AlGaN barrier layer is fabricated by alternately depositing at least one atomic monolayer of GaN and at least one atomic monolayer of AlN until the AlGaN barrier layer reaches a predetermined thickness.

30. The method of claim 25, wherein the channel layer is grown over the entire surface of the support.

31. The method of claim 25, wherein the channel layer is made of at least one of AlN, or GaN, or BN or InN or InGaN.

32. The method of claim 25, wherein the support layer is made of at least one of silicon, or SiC, or AlN, or sapphire, or GaN.

33. The method of claim 25, further comprising depositing a buffer layer of at least one of GaN or AlGaN.

34. The method of claim 25, which further comprises providing a buffer layer on the support before providing the channel layer on the buffer layer, the buffer layer being provided by alternately depositing at least one atomic monolayer of a first binary alloy and at least one atomic monolayer of a second binary alloy until a predetermined buffer layer thickness is obtained.

35. The method of claim 34, wherein the first binary alloy is GaN and the second binary alloy is AlN.
